(19) United States
(12) Patent Application Publication
(10) Pub. No.: US 2012/0307434 A1
(43) Pub. Date: Dec. 6, 2012

(54) ROTARY SUPPORTING DEVICE FOR DISPLAY SCREEN

(76) Inventors: Zhi-Bin Yin, Shen Zhen (CN); Min Zhou, Shanghai (CN)

(21) Appl. No.: 13/518,867

(22) PCT Filed: Nov. 19, 2010
(86) PCT No.: PCT/CN2010/078917

§ 371 Date: Aug. 24, 2012

(30) Foreign Application Priority Data
Dec. 25, 2009 (CN) 200910239010.X

(51) Int. Cl. H05K 7/00

(52) U.S. Cl. 361/679.01

(57) ABSTRACT

The present invention relates to the field of display screens, and provides a rotary supporting device for a display screen, where the display screen is disposed on a host. The rotary supporting device includes two connecting rods. Each of the two connecting rods has one end disposed on an outer side of the display screen and the other end disposed on an outer side of the host through a rotating unit, respectively. The display screen is rotatable along the rotating unit at any angle. Compared with the prior art, in the present invention, by disposing the connecting rods between the host and the display screen, and using the rotating unit to enable the display screen to rotate at any angle, a user can operate the display screen at a desired position and angle, thus diverse operation modes are achieved.

### BACKGROUND OF THE INVENTION

1. Field of the Invention

The present invention relates to the field of display screens, and more particularly to a rotary supporting device for a display screen.

2. Description of the Related Art

At present, display screens have been widely applied in numerous electronic products such as notebook computers, televisions and game machines. Usually, a display screen is fixed to a host, and a user only can operate the display screen at one direction and angle, causing much inconvenience. Accordingly, a display screen capable of rotating on a host has been developed. Such a display screen is connected to a host through a rotating shaft, so that the display screen is rotatable on the host. Taking a notebook computer as an example, there exist the following two types of rotating shafts.

Protruding-type rotating shaft: The greatest advantage of the protruding-type rotating shaft lies in that when being opened, the whole screen is lifted up, and will not shelter a rear part of the notebook computer, so that various ports, heat dissipation holes and the like may be disposed at the rear part of the notebook computer conveniently, which facilitates making full of the space of the notebook computer and increasing the number of ports. Meanwhile, since the protruding-type rotating shaft is not easily blocked during rotation, the screen can be opened at a large angle, which usually may be up to 150° to 180°. The protruding-type rotating shaft is disadvantageous in that, a very large protruding part needs to be designed, in order to ensure the strength and damping of the rotating shaft. In this case, the notebook computer needs to be provided with a thick upper cover so as to cover the rotating shaft. As a result, the protruding-type rotating shaft has a simple operation mode and lacks diverse operations, so that it cannot keep up with changes in technology and fashion trends.

Sunk-type rotating shaft: the sunk-type rotating shaft has connecting points located at a thick part of the host, so that it is unnecessary to increase the thickness of the upper cover of the notebook computer due to the rotating shaft. Meanwhile, when the sunk-type rotating shaft is opened, the screen will sink, and therefore, in some crowded environment, it may be convenient to use the notebook computer with the sunk-type rotating shaft. However, the sunk-type rotating shaft also has some defects. For example, the rear part of the notebook computer is easily sheltered, so that the ports cannot be disposed at the rear part of the notebook computer. For another example, during rotation, the screen is easily blocked by the rear part of the notebook computer, so that through the sunk-type rotating shaft, the screen can only be opened by an angle of 120° to 130° at most. Compared with the protruding type, no significant change has been made in the sunk type, and the usage mode remains unchanged, so that diverse operations cannot be achieved by the user.

### SUMMARY OF THE INVENTION

A technical problem to be solved by the present invention is to overcome the defects of the prior art, and provide a rotary supporting device for a display screen, so that a user may adjust the position and angle of the display screen at will according to different environments and different requirements, thereby achieving diverse operation modes.

To solve the above technical problem, the present invention adopts the following technical solution: a rotary supporting device for a display screen, with the display screen being disposed on a host, where the rotary supporting device comprises two connecting rods, each of the two connecting rods has one end disposed on an outer side of the display screen and the other end disposed on an outer side of the host through a rotating unit, respectively, and the display screen is rotatable along the rotating unit at any angle.

Compared with the prior art, in the present invention, by disposing the connecting rods between the host and the display screen, and using the rotating unit to enable the display screen to rotate at any angle, a user can operate the display screen at a desired position and angle, thus diverse operation modes are achieved.

### BRIEF DESCRIPTION OF THE DRAWINGS

FIG. 1 is a schematic structural view of a supporting device for a display screen according to an embodiment of the present invention, where the display screen is rotated at an angle;

FIG. 2 is a schematic exploded structural view of a supporting device according to a first embodiment of the present invention;

FIG. 3 is a schematic exploded structural view of a supporting device according to a second embodiment of the present invention;

FIG. 4a is a schematic structural view where the display screen is closed according to the embodiments of the present invention;

FIG. 4b is a schematic structural view of a rotating unit where the display screen is closed according to the embodiments of the present invention;

FIGS. 5a and 6a are schematic structural views where the display screen is opened by a certain angle according to the embodiments of the present invention;

FIGS. 5b and 6b are schematic structural views of the rotating unit where the display screen is opened by a certain angle according to the embodiments of the present invention;

FIGS. 7a and 8a are schematic structural views where the display screen faces upwards according to the embodiments of the present invention;

FIGS. 7b and 8b are schematic structural views of the rotating unit where the display screen faces upwards according to the embodiments of the present invention; and

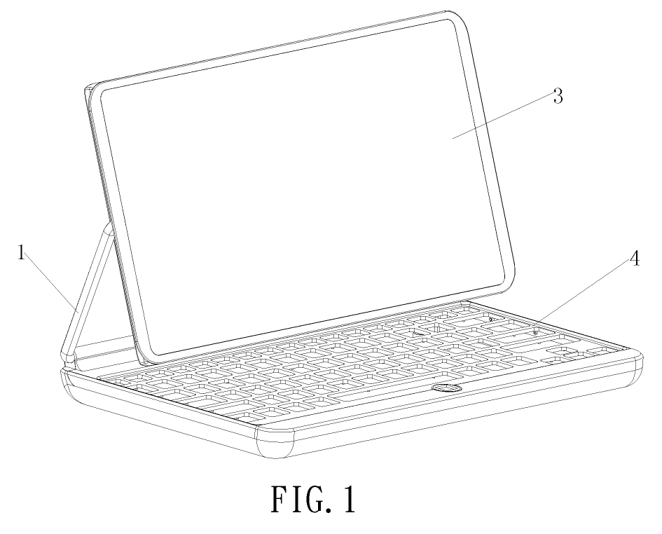

FIG. 1a is a schematic structural view of the supporting device where the display screen is rotated to the state of FIG. 1 according to the embodiment of the present invention.

### DETAILED DESCRIPTION OF THE PREFERRED EMBODIMENTS

A further description is given below with reference to the most preferred embodiments shown in the accompanying drawings.

FIG. 1 is a schematic structural view of a rotary supporting device for a display screen according to the present invention. The rotary display device includes a display screen 3. The display screen 3 is connected to a host 4. A connecting rod 1 is connected between the display screen 3 and the host 4. The connecting rod 1 functions to support the display screen.

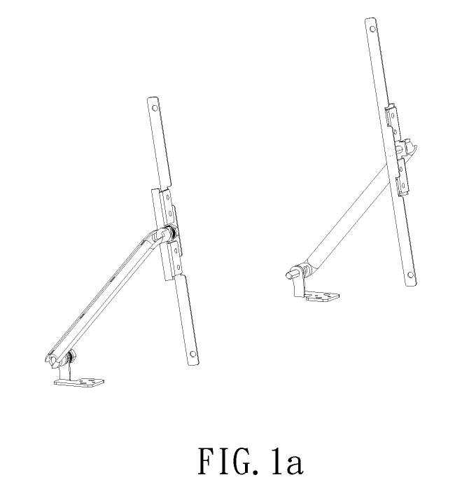

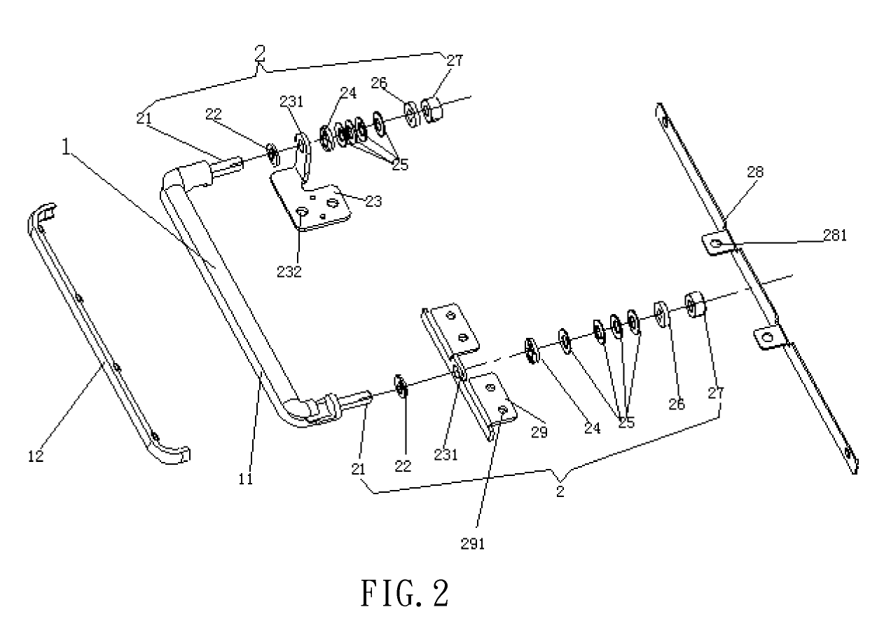

FIG. 2 is a schematic exploded view of a rotary supporting device according to a first embodiment of the present invention. The connecting rod 1 is connected to the display screen 3 or the host 4 through a rotating unit 2. The rotary supporting device according to the embodiment of the present invention comprises two connecting rods 1. Each of the connecting rods 1 has a U-shaped structure. A first connecting rod 1 has one end connected to the display screen 3 through the rotating unit 2 and the other end connected to the host 4 through the rotating unit 2. The display screen 3 is rotatable about the rotating unit 2 at any angle.

As shown in FIG. 2, the rotating unit 2 according to the embodiment of the present invention is a rotating shaft structure. The rotating shaft structure includes threaded rods 21. The threaded rods 21 may be rectangular-shaped or circular-shaped. The threaded rods 21 are disposed on the connecting rod 1, and may be formed integrally as one piece with the connecting rod 1. Alternatively, a hole is formed in each end portion of the connecting rod 1, and a corresponding one of the threaded rods 21 is nested or screwed in the hole. The rotating shaft structure further includes cams 24 and fixing plates 23, 29. The fixing plates 23, 29 are provided with cam friction plates 231 and 291, respectively. The cam friction plates 231, 291 and the cams 24 are respectively provided with a through hole. One end of each threaded rod 21 is connected to the connecting rod 1, and the other end is connected to the display screen 3 or the host 4 through the respective through holes. A screw hole 232 is formed in the fixing plate 23 in the embodiment of the present invention, and through the screw hole, the rotating unit 2 is fixed to the host 4 by a screw. The rotary supporting device according to the embodiment of the present invention further comprises a fixing member 28. Screw holes 281 are formed in the fixing member 28, and screw holes 291 are formed in the fixing plate 29. By overlapping the screw holes 291 with the screw holes 281 in the fixing member 28, one end of the connecting rod 1 of the rotating unit 2 is fixed to the display screen 3 by screws.

As shown in FIG. 2, the rotating shaft structure according to the embodiment of the present invention further includes elastic members 25. The elastic members 25 are sleeved on the threaded rods 21, respectively. Each of the elastic members 25 may be a spring, or may be formed by several elastic pieces. The embodiment of the present invention is exemplified using the elastic members 25 formed by several elastic pieces, but is not limited to thereto.

As shown in FIG. 2, the rotating shaft structure according to the embodiment of the present invention further includes limiting members 22, 27. Each of the limiting members 22 is a limiting piece, and disposed at one end of a corresponding one of the threaded rods 21 connected to the connecting rod 1. Each of the limiting members 27 is a nut. The nut is screwed on the corresponding threaded rod 21, and disposed at one end of the corresponding threaded rod 21 connected to the display screen 3 or the host 4. The limiting members 22, 27 are each provided with a hole therein, and each threaded rod 21 extends through the holes of the two corresponding limiting members 22, 27 to limit and fix the rotating shaft structure.

The first embodiment of the present invention is configured in the following manner. First, the connecting rod 1 is connected to the threaded rods 21. Then, the limiting pieces 22, the cam friction plates 231, the cams 24, the elastic members 25, and the limiting nuts 27 of the rotating unit 2 are sleeved together in sequence. To prevent detachment or loosening of the nuts due to wearing of the nuts 27 and rotation of the display screen 3, a washer 26 may be disposed between each nut 27 and the corresponding elastic member 25. Afterwards, the fixing plate 23 is fixed to the host 4. Finally, the fixing plate 29 and the fixing member 28 are stacked and fixed on the display screen 3. The fixing plates 23, 29 and the fixing member 28 may be fixed in any order. In the first embodiment of the present invention, friction damping is produced by a friction force between each cam friction plate 231 and the corresponding cam 24 and an elastic force of each elastic member 25 to drive the display screen to rotate, so that in use, the display screen can be rotated freely, and therefore may be operated by the user at will.

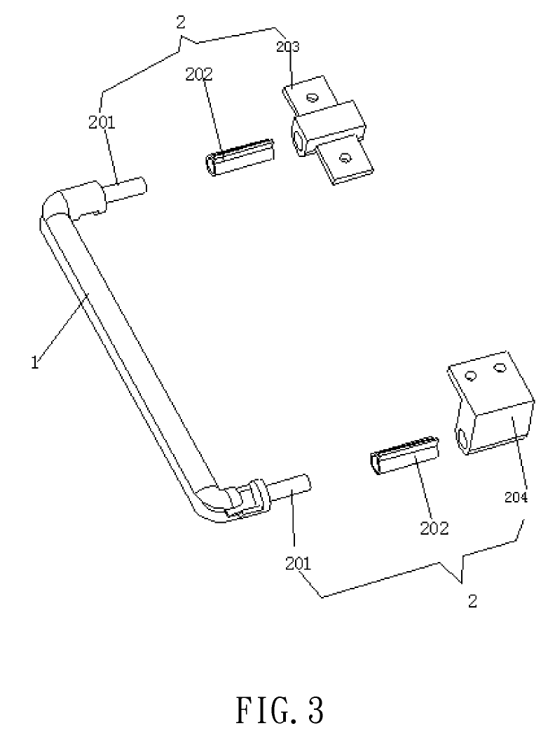

FIG. 3 is a schematic exploded structural view of a second embodiment of the present invention. The rotating unit is a sleeve structure, which includes sleeves 202. Each of the sleeves 202 includes an inner shaft 201. One end of the inner shaft 201 is connected to the connecting rod 1, and the other end extends through the corresponding sleeve 202 to be connected to the display screen 3 or the host 4. The sleeves 202 are provided with fixing members 203, 204 at an end. One of the sleeves 202 is fixed to the display screen 3 through the fixing member 203, and the other is fixed to the host 4 through the fixing member 204. In the second embodiment of the present invention, damping is produced through friction between each sleeve 202 and the corresponding inner shaft 201 to drive the display screen 3 to rotate, which also can achieve rotation at any angle.

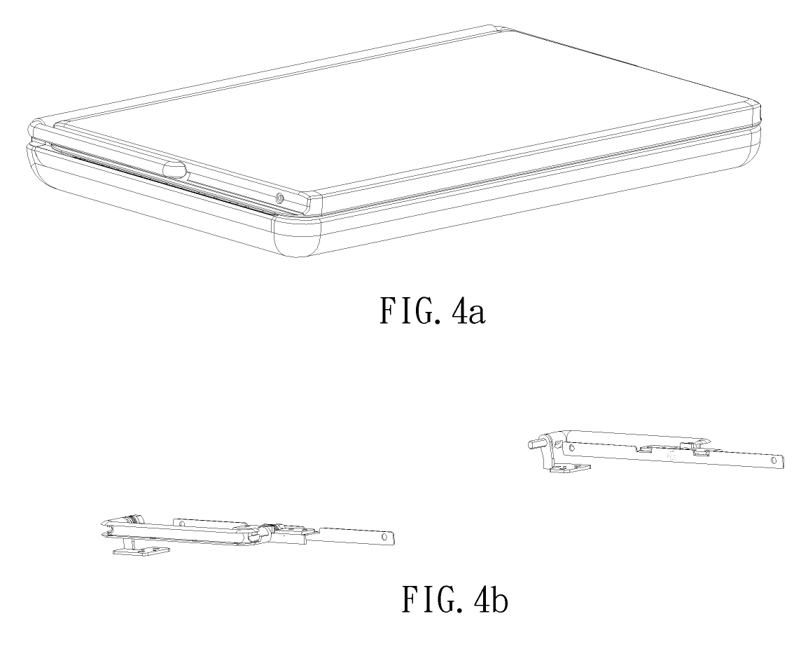

FIG. 4a is a schematic structural view where the rotary supporting device is closed according to the first embodiment or the second embodiment of the present invention, and FIG. 4b is a schematic structural view of the rotating unit 2 where the display screen 3 is closed.

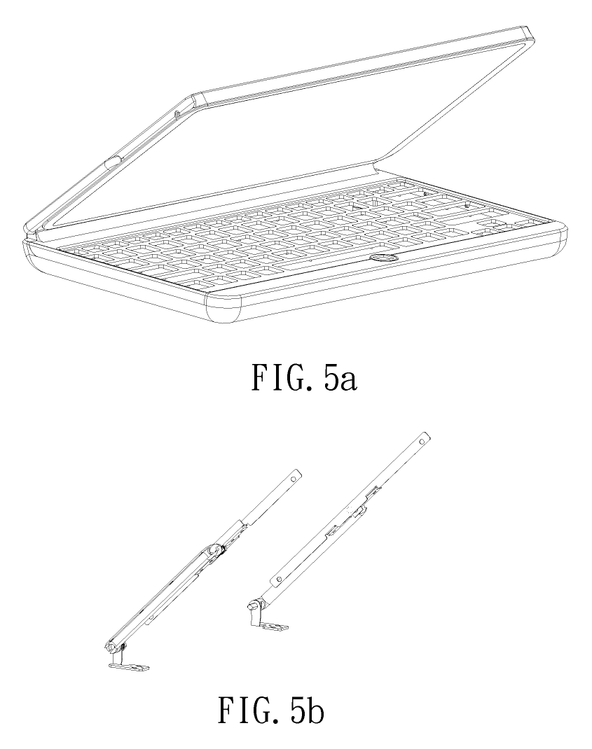

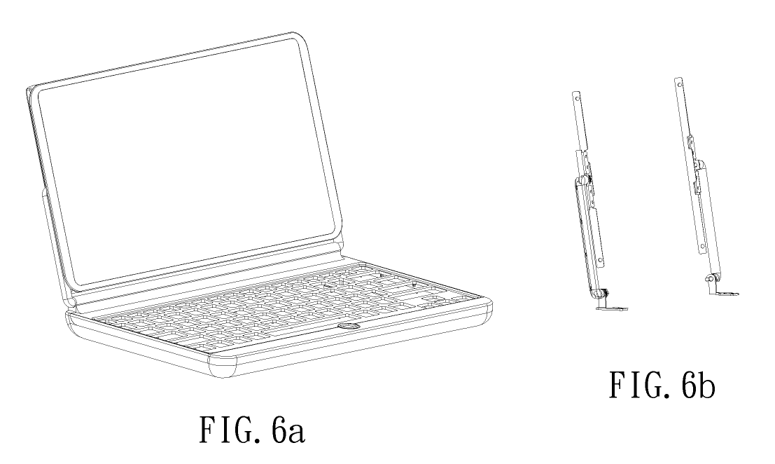

FIGS. 5a and 6a are schematic structural views where the display screen is opened by different angles, and FIGS. 5b and 6b are schematic structural views of the rotating unit 2 where the display screen 3 is opened by different angles.

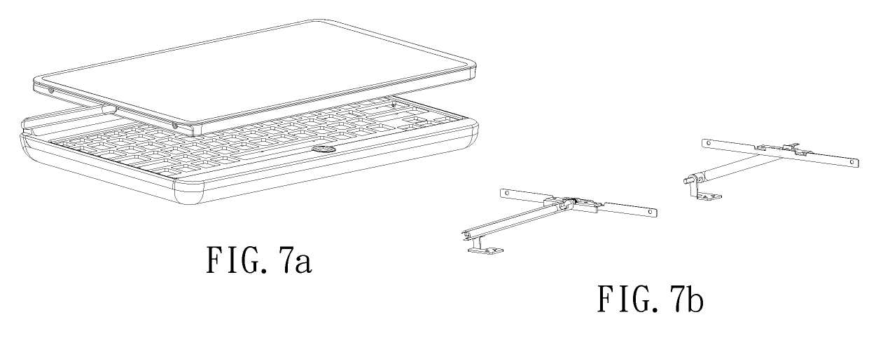

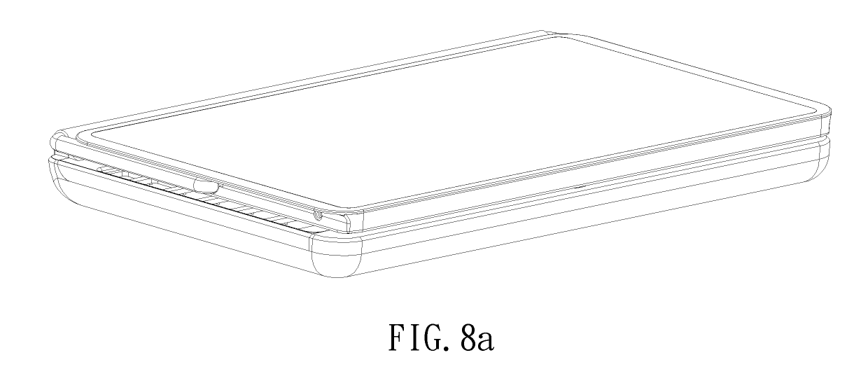

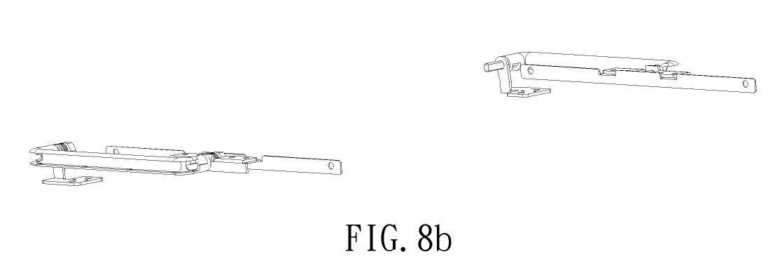

FIG. 7a is a schematic structural view where the display screen 3 faces upwards, where the display screen 3 is supported above the host 4, but are not superposed on the host 4; FIG. 8a is a schematic structural view where the display screen 3 faces upwards, where the display screen 3 is supported on and superposed on the host 4; and FIGS. 7b and 8b are respectively a schematic structural view of the rotating unit 2 in either case.

FIG. 1 is also a schematic structural view after the rotating unit 2 is rotated at a certain angle, where the connecting rod 1 and the display screen 3 form a stable triangular structure, and FIG. 1a is a schematic structural view of the rotating unit 2 when being in the state of FIG. 1.

The connecting rod 1 according to the embodiments of the present invention is provided with a groove 11 therein. The groove 11 is a wiring groove for connection wires of the host 4. The groove 11 is provided with a connecting rod stopper 12, for concealing all the connection wires in the groove 11.

The connecting rod 1 according to the embodiments of the present invention may be a hollow tube, which serves as a wiring groove for connection wires of the host 4 and the display screen 3.

The rotating shafts and the sleeves according to the embodiments of the present invention may be disposed on two sides of the display screen 3 or the host 4 at any position. Any alternative in position is included within the scope of the present invention.

The embodiments of the present invention are applicable to the field of all display screens, but have been exemplified using a notebook computer as an example only.

The implementation of the present invention is not limited to those disclosed in the above embodiments. Any specific rotary supporting device for a display screen obtained through simple deduction and replacement based on the above design concept shall fall within the scope of the present invention.

What we claim is:

1. A rotary supporting device for a display screen, said display screen being disposed on a host, wherein said rotary supporting device comprises two connecting rods, each of said two connecting rods having one end disposed on an outer side of said display screen and the other end disposed on an outer side of said host through a rotating unit, respectively, and said display screen being rotatable along said rotating unit at any angle.

2. The rotary supporting device for a display screen according to claim 1, wherein said rotating unit is a rotating shaft structure, said rotating shaft structure including threaded rods, cams and fixing plates, a cam friction plate being disposed on each of said fixing plates, said cam friction plates and said cams being respectively provided with a through hole therein, and each of said threaded rods having one end connected to a corresponding one of said connecting rods and the other end extending through corresponding those of said through holes to be connected to said display screen or said host.

3. The rotary supporting device for a display screen according to claim 2, wherein said rotating shaft structure further includes elastic members, each of said elastic members being sleeved on a corresponding one of said threaded rods.

4. The rotary supporting device for a display screen according to claim 3, wherein said rotating shaft structure further includes limiting members, each of said limiting members being provided with a hole therein, and being sleeved on either end portion of said rotating shaft structure through a corresponding one of said threaded rods.

5. The rotary supporting device for a display screen according to claim 1, wherein said rotating unit is a sleeve structure, said sleeve structure including sleeves, each of said sleeves including an inner shaft, said inner shaft having one end connected to said corresponding connecting rod and the other end extending through said corresponding sleeve to be connected to said display screen or said host.

6. The rotary supporting device for a display screen according to claim 5, wherein one end of each sleeve is provided with a fixing member, said sleeve being fixed to said display screen or said host through said fixing member.

7. The rotary supporting device for a display screen according to claim 1, wherein each of said connecting rods is provided with a groove or hollow tube, said groove or hollow tube serving as a wiring groove for connection wires of said host.

8. The rotary supporting device for a display screen according to claim 7, wherein said groove is provided with a connecting rod stopper.

9. The rotary supporting device for a display screen according to claim 2, wherein each of said threaded rods and each of said inner shafts are formed integrally as one piece with said corresponding connecting rod respectively.

10. The rotary supporting device for a display screen according to claim 2, wherein a hole is formed in each end portions of each connecting rod, said corresponding threaded rod and said corresponding inner shaft being nested or screwed in said hole respectively.
